(19) United States
(12) Patent Application Publication
(10) Pub. No.: US 2025/0163607 A1
(43) Pub. Date: May 22, 2025

(54) LOW TEMPERATURE EPI CHAMBER

(71) Applicant: Applied Materials, Inc., Santa Clara, CA (US)

(72) Inventors: Justin GAU, Santa Clara, CA (US); Shekhar ATHANI, Bangalore (IN); Rahul KOZHIKKALKANDI, Bangalore (IN); Nithin ALEX, Bangalore (IN); Adib KHAN, Santa Clara, CA (US); Qiwei LIANG, Fremont, CA (US); Lancelot HUANG, San Jose, CA (US); Junghoon KIM, Santa Clara, CA (US); Hyunjun KIM, Campbell, CA (US); Douglas A. BUCHBERGER, JR., Livermore, CA (US); Vishwas Kumar PANDEY, Madhya Pradesh (IN); Srinivas D. NEMANI, Sunnyvale, CA (US); Ellie Y. YIEH, San Jose, CA (US); Dmitry LUBOMIRSKY, Cupertino, CA (US)

(21) Appl. No.: 18/516,728

(22) Filed: Nov. 21, 2023

(51) Int. Cl. C30B 25/08; C30B 25/12; C30B 25/14

(52) U.S. Cl. CPC C30B 25/08; C30B 25/12; C30B 25/14

(57) ABSTRACT

Disclosed herein is a processing chamber for a low temperature epitaxy deposition and components of the same. The processing chamber includes a dome lid coupled with a lid liner via a lid liner separator; a remote plasma source disposed outside the dome lid and operable to energize a process gas; a gas ring disposed under the dome lid and coupled with a gas ring liner via a gas ring liner separator; a showerhead disposed under the gas ring; a susceptor disposed below the showerhead and operable to heat a substrate by conduction; and a side wall disposed under the gas ring and coupled with a wall liner via a wall liner separator. The cleaning method of the processing chamber is also disclosed.

### BACKGROUND

### Field

The present disclosure relates to an epitaxy growth system operable at a low temperature, and more specifically relates to an epitaxy growth system capable of operating below 400° C.

### Description of the Related Art

Epitaxy refers to processes used to grow a thin crystalline layer (known as an EPI layer) on a crystalline substrate. The EPI layer on a semiconductor substrate can improve the electrical characteristics of the surface and make the substrate and the surface suitable for highly complex microprocessors and memory devices.

Conventional systems generally operate at high temperatures, such as above 800° C. This operating temperature is relatively high, which not only needs a high thermal budget but also limits the application of the EPI process to those materials that can survive a high processing temperature.

Thus, a need exists for an improved epitaxy system.

### SUMMARY

Disclosed herein is a processing chamber for a low temperature epitaxy deposition and components of the same. The processing chamber includes a dome lid coupled with a lid liner via a lid liner separator; a remote plasma source disposed outside the dome lid and operable to energize a process gas; a gas ring disposed under the dome lid and coupled with a gas ring liner via a gas ring liner separator; a susceptor disposed below the showerhead and operable to heat a substrate by conduction; and a side wall disposed under the gas ring and coupled with a wall liner via a wall liner separator.

A method for cleaning a low temperature EPI chamber is further disclosed. The method includes raising a temperature of a substrate disposed in the EPI chamber above about 400° C.; lowering a pressure within the EPI chamber below about 100 m Torr; generating Ar plasma in the EPI chamber via ICP coils; maintaining the temperature and the pressure for a determined period while the EPI chamber contains the Ar plasma; introducing chlorine containing gas into the EPI chamber; and flowing a purge gas into gaps formed between internal liners and walls of the EPI chamber.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 illustrates a schematic top view of a processing system, according to an embodiment of the present application.

FIG. 2 illustrates a schematic cross-sectional view of a processing chamber, according to an embodiment of the present application.

FIG. 3 illustrates a schematic cross-sectional view of a processing chamber, according to an embodiment of the present application.

FIG. 4a illustrates a schematic cross-sectional view of a dome lid, according to an embodiment of the present application.

FIG. 4b illustrates a schematic perspective view of a dome lid, according to an embodiment of the present application.

FIG. 5a illustrates a schematic cross-sectional view of a configuration of Callout 4-A in FIG. 4a, according to an embodiment of the present application.

FIG. 5b illustrates a schematic perspective view of the top baffle 236 shown in FIG. 5a, according to an embodiment of the present application.

FIG. 5c illustrates a schematic cross-sectional view of the top baffle 236 shown in FIG. 5a, according to an embodiment of the present application.

FIG. 6 illustrates a schematic cross-sectional view of a configuration of Callout 4-B in FIG. 4b, according to an embodiment of the present application.

FIG. 7a illustrates a schematic perspective view of a gas ring liner, according to an embodiment of the present application.

FIG. 7b illustrates a schematic perspective view of the coupling configuration among the gas ring, the gas ring liner, and the side nozzles, according to an embodiment of the present application.

FIG. 7c illustrates a schematic cross-sectional view of the coupling configuration among the gas ring, the gas ring liner, and the side nozzles, according to an embodiment of the present application.

FIG. 7d illustrates a schematic cross-sectional view of a side nozzle 240, according to an embodiment of the present application.

FIG. 8 illustrates a schematic cross-sectional view of a processing chamber including the gas ring and the susceptor, according to an embodiment of the present application.

FIG. 9a illustrates a schematic top view of the showerhead, according to an embodiment of the present application.

FIG. 9b illustrates a schematic top view of the showerhead, according to an embodiment of the present application.

FIG. 10a illustrates a schematic cross-sectional view of the susceptor, according to an embodiment of the present application.

FIG. 10b illustrates a schematic top view of the heater body 1012 according to an embodiment.

FIG. 10c illustrates a schematic cross-sectional view of the heater body 1012.

FIG. 11 illustrates a schematic perspective view of the bottom liner, according to an embodiment of the present application.

FIG. 12 illustrates a schematic flow path of a purge gas according to an embodiment of the present application.

FIG. 13 illustrates operations of a cleaning method, according to an embodiment of the present application.

FIG. 14a illustrates a schematic cross-sectional view of a susceptor, according to an embodiment.

FIG. 14b illustrates a schematic cross-sectional view of a heater puck, according to an embodiment.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The disclosure contemplates that terms such as “couples,” “coupling,” “couple,” and “coupled” may include but are not limited to welding, fusing, melting together, interference fitting, and/or fastening such as by using bolts, threaded connections, pins, and/or screws. The disclosure contemplates that terms such as “couples,” “coupling,” “couple,” and “coupled” may include but are not limited to integrally forming. The disclosure contemplates that terms such as “couples,” “coupling,” “couple,” and “coupled” may include but are not limited to direct coupling and/or indirect coupling, such as indirect coupling through components such as links, blocks, and/or frames.

Disclosed herein are an EPI chamber for a low temperature EPI growth and components of the same. The EPI chamber includes a susceptor that conductively heats a substrate using a resistive heater. A radiative heat source may not be needed in the EPI chamber of the present application, essentially reducing the frequency to clean the dome of the EPI chamber. The substrate temperature during processing is controlled to be below 800° C., 600° C., 500° C., or even lower. The Epi growth rates at these low temperatures are compensated by increasing gas/plasma temperature and activating the surface (compensating lower surface temperature) of the substrate to increase mobility of adatoms landed on the substrate surface. Thus, one or more plasma sources are included in the EPI chamber for energizing the process gas. The plurality of plasma sources may be disposed around pipes of gas feeds, above and/or below the showerhead around the dome lid and/or side walls of the EPI chamber.

To further increase the growth rate at the low temperature, the kinetic energy of the incident ions/radicals may also be increased. The susceptor may be biased by an RF voltage to increase the kinetic energy of the adatoms independently from the rotational/vibrational modes.

To reduce energy loss to the environment and protect the other parts of the EPI chamber from erosion, the EPI chamber includes a plurality of internal liners that thermally isolate the dome and side walls of the EPI chamber from internal heat. As the liners are made of materials of low thermal conductance, such as quartz, and are different from the dome and walls of the EPI chamber, the internal liners are separated from adjacent parts by separators to avoid thermal stress caused by mismatch of coefficient of thermal expansion (CTE). A process of purging process gases from the gaps between the internal liners and outside parts is implemented to prevent unnecessary deposition of materials or byproducts in those gaps and to prevent possible contamination during the processing of the next substrate.

To provide axisymmetric gas flow into the processing region, a gas feed with a plurality of feeding locations is included in the dome of the EPI chamber. The gas feed includes a top flow baffle disposed at the center of the dome. The gas feed further includes a plurality of side nozzles disposed right above the showerhead around the side walls of the dome lid. A gas ring couples the plurality of the side nozzles and is protected by a gas ring liner. Optionally, the process gases may be provided to a gas plenum first and then flow through a showerhead into a processing region above the susceptor.

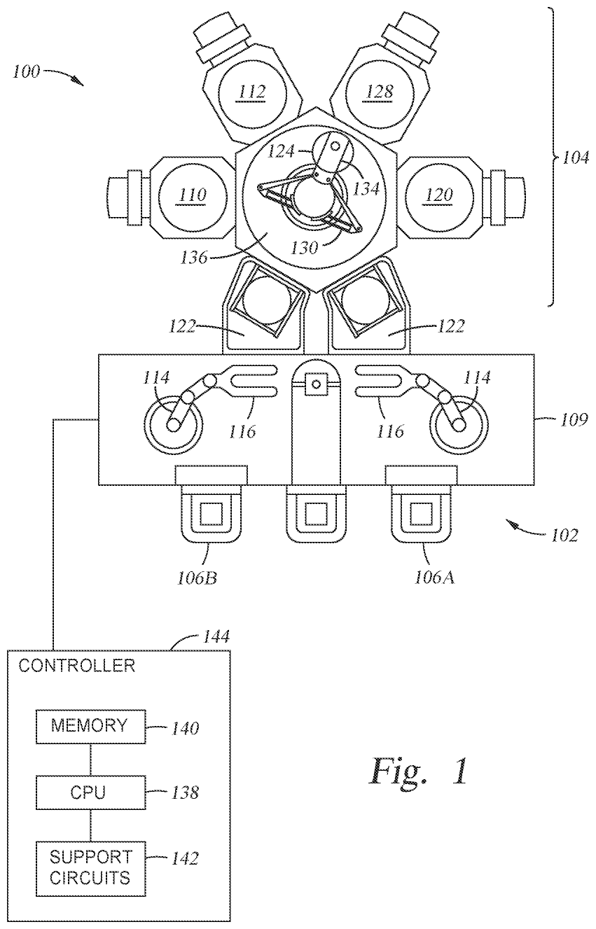

FIG. 1 illustrates a schematic top view of a processing system 100, according to one or more embodiments. The processing system 100 includes one or more load lock chambers 122 (two are shown in FIG. 1), a processing platform 104, a factory interface 102, and a controller 144. In one or more embodiments, the processing system 100 may be adapted for use in a CENTURA® integrated processing system provided by Applied Materials, Inc., located in Santa Clara, California. It is contemplated that other processing systems (including those from other manufacturers) may be adapted to benefit from the disclosure.

The processing platform 104 includes a plurality of processing chambers 110, 112, 120, 128, the one or more load lock chambers 122, and a transfer chamber 136 that is coupled to the one or more load lock chamber 122. The transfer chamber 136 can be maintained under vacuum, or can be maintained at an ambient (e.g., atmospheric) pressure. Two load lock chambers 122 are shown in FIG. 1. The factory interface 102 is coupled to the transfer chamber 136 through the load lock chambers 122. According to an embodiment, each one of the plurality of processing chambers 110, 112, 120, and 128 may be a low temperature EPI chamber as set forth in the present application. According to an embodiment, one of the plurality of processing chambers 110, 112, 120, and 128 may be a preclean chamber configured to remove oxides from a substrate.

In one or more embodiments, the factory interface 102 includes at least one docking station 109 and at least one factory interface robot 114 to facilitate the transfer of substrates 124. The docking station 109 is configured to accept one or more front opening unified pods (FOUPs). Two FOUPS 106A, 106B are shown in the implementation of FIG. 1. The factory interface robot 114 having a blade 116 disposed on one end of the robot 114 is configured to transfer one or more substrates from the FOUPS 106A, 106B, through the load lock chambers 122, to the processing platform 104 for processing. Substrates being transferred can be stored at least temporarily in the load lock chambers 122.

Each of the load lock chambers 122 has a first port interfacing with the factory interface 102 and a second port interfacing with the transfer chamber 136. The load lock chambers 122 are coupled to a pressure control system (not shown) which pumps down and vents the load lock chambers 122 to facilitate passing the substrates between the environment (e.g., vacuum environment) of the transfer chamber 136 and a substantially ambient (e.g., atmospheric) environment of the factory interface 102.

The transfer chamber 136 has a vacuum robot 130 disposed therein. The vacuum robot 130 has one or more blades 134 (two are shown in FIG. 1) capable of transferring the substrates 124 between the load lock chambers 122 and the processing chambers 110, 112, 120, and 128.

The controller 144 is coupled to the processing system 100 and is used to control processes and methods, such as the operations of the methods described herein (for example the operations of the methods as described in other parts of the present application). The controller 144 includes a central processing unit (CPU) 138, a memory 140 containing instructions, and support circuits 142 for the CPU. The controller 144 controls various items directly, or via other computers and/or controllers.

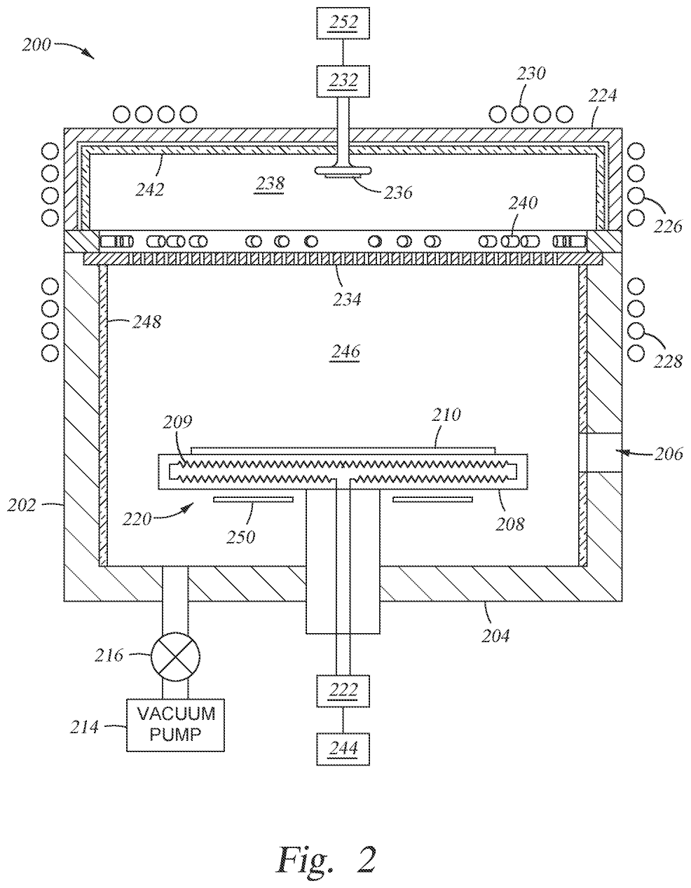

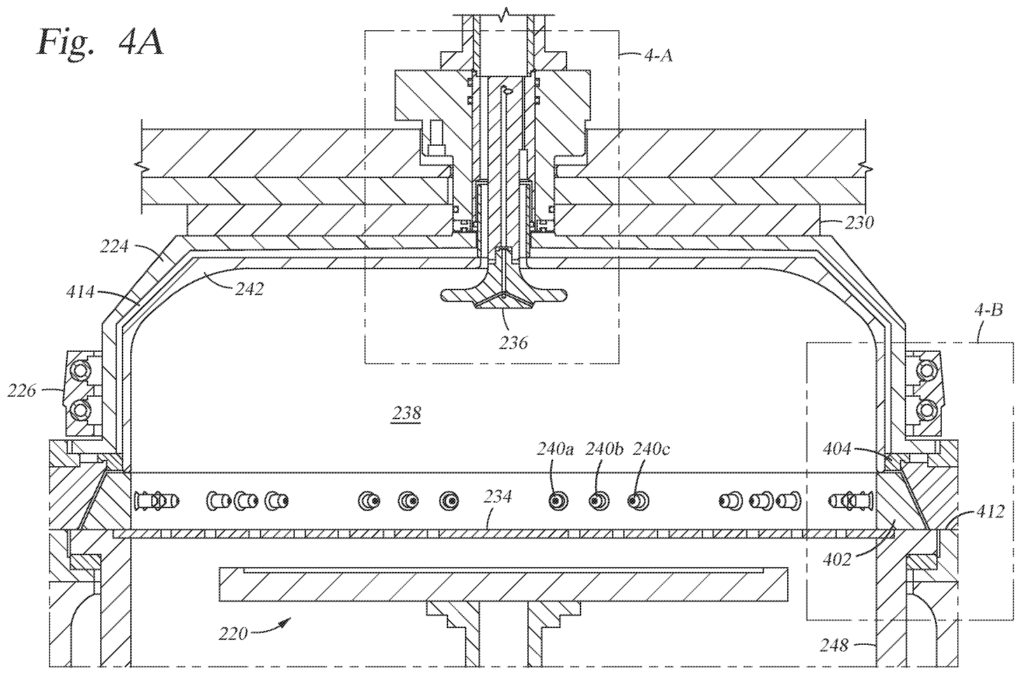

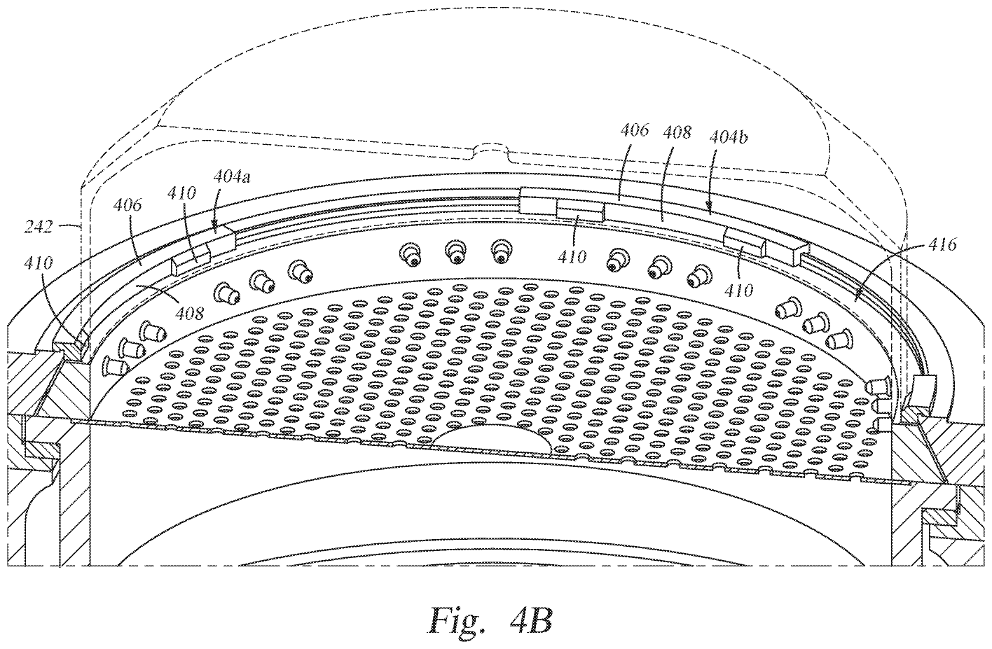

FIG. 2 illustrates a schematic cross-sectional view of a processing chamber 200 according to an embodiment. The processing chamber 200 may be any one of the processing chambers 110, 112, 128, and 120 as shown in FIG. 1 and operable to deposit an EPI layer at a low temperature. The processing chamber 200 in FIG. 2 includes side walls 202, a bottom 204, a chamber lid 224, and a plurality of internal liners, including an upper lid liner 242 and a lower wall liner 248. The chamber lid 224, the side walls 202, and the bottom 204 together enclose a processing region 246. A susceptor 220 is disposed in the processing region 246 and supports a substrate 210 thereon during processing. The side walls 202 include a plurality of ports 206 for transferring the substrate 210 in or out of the processing chamber 200. The upper lid liner 242 and the lower wall liner 248 are configured to insulate the lid 224 and the side walls 202, respectively, from the internal heat. According to an embodiment, the chamber lid 224 may be made of metal, such as aluminum or stainless steel, and the upper lid liner 242 and the lower wall liner 248 may be made of thermal insulators, such as ceramic or quartz. The liners are configured to conform to the shape of the lid 224 and the side walls 202. Other liners, such as a gas ring liner 402 in FIG. 4a, may also be utilized to protect other components of the processing chamber 200.

The processing chamber 200 further includes a vacuum pump 214 and a plurality of gas sources 232 containing a carrier gas, a deposition gas, a purge gas, and a cleaning gas. The gases may be provided into the processing chamber via a gas feed. The gas feed may include a top baffle 236 disposed at a central part of the lid 224 and a plurality of side nozzles 240 disposed along side walls of the lid 224. The remote plasma source 252 may be coupled with the gas feed of one or more of the gas sources 232 and configured to energize each process gas independently or energize a mixture of two or more of the process gases. The energized process gas is provided to the chamber 200 via the top baffle 236. The vacuum pump 214 is coupled to the processing chamber 200 and configured to adjust the vacuum level within the process region 246 via a valve 216. Vacuum pump 214 is also configured to evacuate spent gases from the processing chamber 200. According to an embodiment, the wall liners 248 includes an open lower end configured to allow process gases to flow through.

Optionally, the processing chamber 200 also includes a gas plenum 238 contained and a showerhead 234. The gas sources 232 provide process gases into the gas plenum 238 first via the top baffle 236. The gas showerhead 234 includes a plurality of conduits that allow the process gases to flow through. The gas plenum 238 and the showerhead 234 are configured to improve an axisymmetric flow pattern of process gases into the process region 246.

The processing chamber 200 further includes a heating unit 222 coupled with the susceptor 220. The heating unit 222 includes heating elements 209 disposed in a body 208. According to an embodiment, the heating elements 209 are resistive heaters. The heating unit 222 may also include bias electrodes configured to provide bias voltage to the susceptor 220. The bias electrodes can increase the kinetic energy of the radical/ions in the process gases and add directionality. The heating unit 222 and the susceptor 220 may be coupled with a lifter 244 configured to lift up and lower down the susceptor 220 and the heating unit 222. The heating unit 222 is configured to adjust the temperature of the substrate within a predetermined range, such as 100 to 800° C., 100 to 700° C., 100 to 600° C., 100 to 500° C., 100 to 400° C., or other suitable temperature range.

As the substrate 210 has a low temperature during EPI growth, the processing chamber 200 includes a plurality of plasma sources 226, 228, 230 disposed at various locations of the processing chamber 200 to energize the process gases. After energization, the reactants of the process gases, such as radicals and ions, have a high energy that can increase both growth rate and uniformity of deposited materials. As shown in FIG. 2, a plasma source 230 may be disposed at a top surface of the lid 224, and/or another plasma source 226 is disposed around the side walls of the lid 224. The plasma sources 230 and 226 are operable to energize the process gases above the showerhead 234, i.e. within the gas plenum 238. Another plasma source 228 may disposed along side walls 202 and is operable to energize the process gases between the showerhead 234 and the susceptor 220. Furthermore, a remote plasma source 252 may be disposed outside the lid 224 and operable to energize the process gases prior to entering the plenum 238. The plasma sources 252, 230, 226, and 228 can be controlled independently or collectively by the controller 114 depicted in FIG. 1.

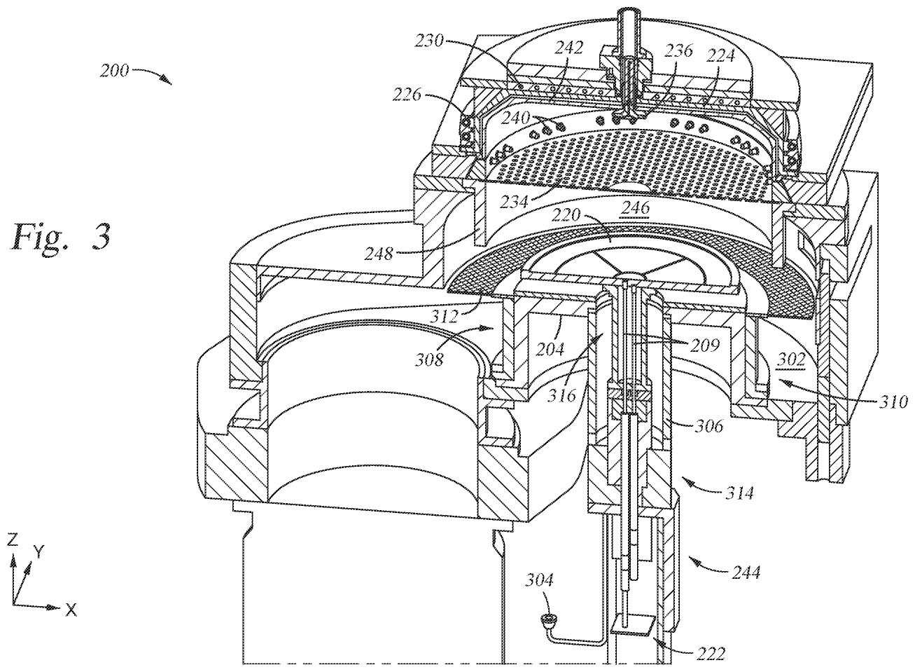

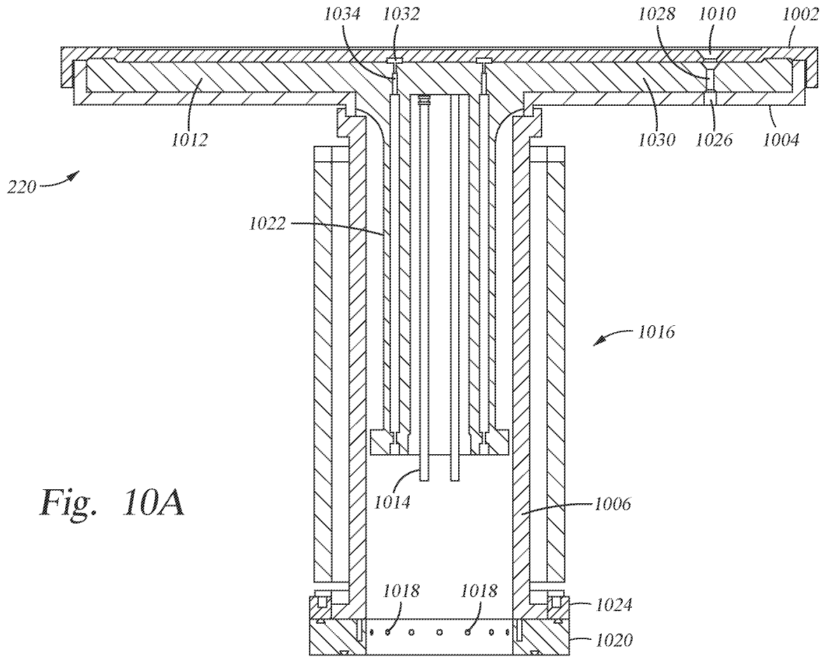

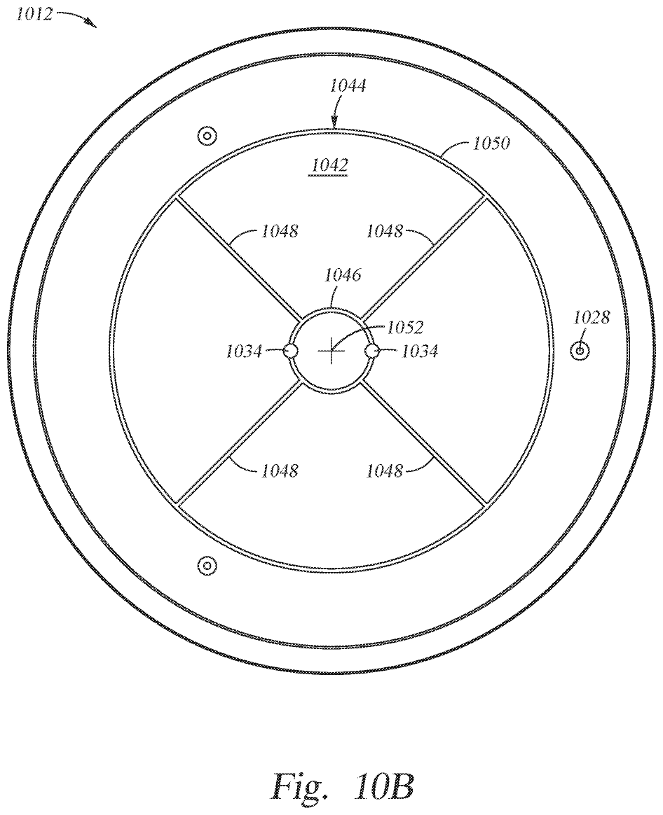

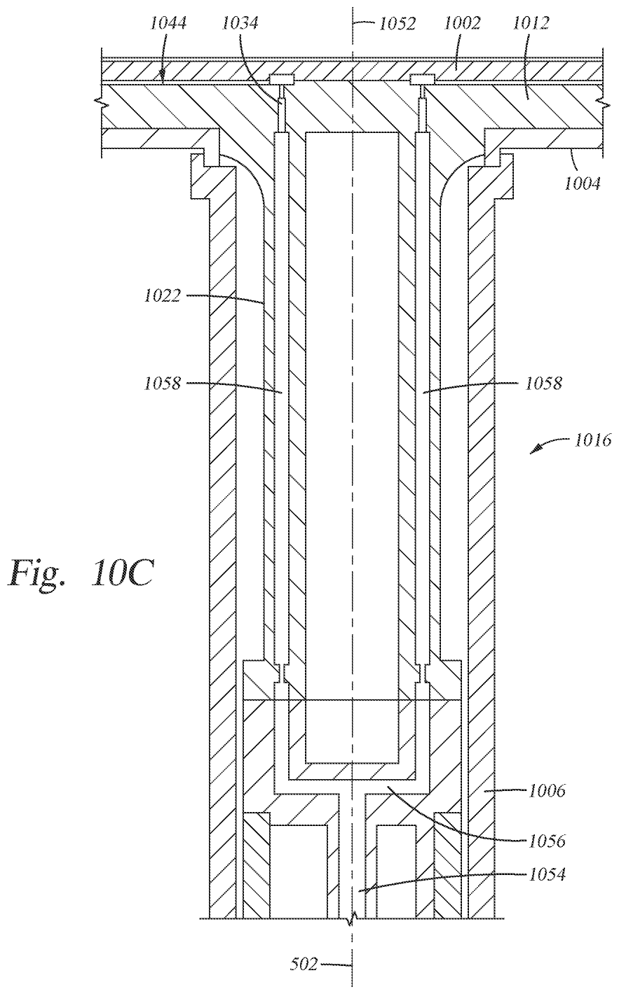

FIG. 3 illustrates a schematic cross-sectional view of a processing chamber 200 according to an embodiment. Similar components in FIGS. 2 and 3 are indicated with identical reference numerals. Comparing with FIG. 2, the processing chamber 200 in FIG. 3 further includes a vacuum plenum 302, a protective sleeve 306 for the susceptor 220 (also shown as 1016 in FIG. 10), and a purge gas inlet 304. The vacuum plenum 302 couples the vacuum pump 214 with the processing region 246 via the bottom of the processing chamber 200. The vacuum plenum 302 is configure to even the vacuum level across the process region 246 such that process gases within the processing region 246 are evenly drawn across the substrate disposed on the susceptor 220. The vacuum plenum 302 couples with the vacuum pump 214 via a lower surface of the vacuum plenum 302 and couples with the process region 246 via an upper surface of the vacuum plenum 302. The vacuum pump 214 can be side-mounted or coaxially-mounted with regard to the processing region 246. According to an embodiment, the upper surface of the vacuum plenum 302 may be a charged screen 312 that is capable of attracting radicals in the plasma and preventing the same from entering the vacuum plenum 302 and subsequent processing lines. The charge screen 312 can also function as a pump liner configured to correct the skew of pressure caused by an offset pump. For example, a higher density of holes may be arranged at a distal end of the charge screen 312, which is far away from the vacuum pump 214, than a proximal end of the charge screen, which is adjacent to the vacuum pump 214. In another example, holes at the distal end may have a larger diameter than holes at the proximal end.

FIG. 3 illustrates a side-mounted vacuum pump 214, where the vacuum plenum 302 extend from the vacuum pump 214 to surround a support column of the susceptor 220 along the bottom 204 of the processing chamber 200. The vacuum plenum 302 includes a proximate end 308 that is close to the vacuum pump 214 and a distal end 310 that is distant to the vacuum pump 214. The proximate end 308 is configured to have a larger dimension than the distal end 310 to facilitate an even drawing of the process gases from the processing region 246.

As the susceptor 220 may be lifted up by the lifter 244, the sleeve 306 is configured to provide a purged conduit 316 for the susceptor 220 to move up and down without leaking a substantial amount of process gases. A purge gas flows through the purged conduit 316 to prevent the deposition of materials below the susceptor 220. A detailed description of the sleeve 306 and the susceptor 220 will be provided later with regard to FIG. 10a. The purge gas inlet 304 is coupled with a purge gas source (not shown) and is configured to flow the purge gas into the conduit formed by the sleeve 306.

FIG. 4a illustrates a schematic cross-sectional view of the processing chamber 200 according to an embodiment. Similar components in FIGS. 2 and 4a are indicated with identical reference numerals. Comparing with FIG. 2, FIG. 4a further shows that a plurality of side nozzles 240a, 240b, and 240c are coupled to a gas ring liner 402. According to an embodiment, each process gas may have a dedicated side gas nozzle. For example, the carrier gas may flow through the gas nozzle 240a, the deposition gas may flow through the gas nozzle 240b, and the cleaning gas may flow through the gas nozzle 240c. According to another embodiment, one side gas nozzle may be shared by a plurality of process gases. The side gas nozzles 240a, b and c are evenly distributed around the gas ring liner 420. In one example, a total of 36 side gas nozzles 240 are provided.

The gas ring liner 402 is disposed between the lid liner 242 and the wall liner 248. The wall liner 248 is configured to support both the gas ring liner 402 and, optionally, the showerhead 234. The lid liner 242 rests at a top surface 412 of the gas ring liner 402. A clearance gap is formed between the lid liner 242 and the dome lid 224. A plurality of separators 404 are disposed in the clearance gap to maintain the clearance. The lid liner 242, the gas ring liner 402, and the wall liner 248 may be made of materials having low thermal conductance and/or having resistance to the etch chemistry occurred inside the processing chamber. For example, the lid liner 242 is made of quartz or ceramic. The liners also protect other chamber parts from etch chemistry. The separators 404 are used to prevent the lid and gas ring liners from contacting other parts. The separators 404 may be made of materials that are stable in a wide temperature working range and inert to process gases. For example, the separators 404 may be made of polytetrafluoroethylene (PTFE), perfluoroalkoxy alkane (PFA), or other suitable materials. According to an embodiment, the separators 404 may be disposed at a top surface 416 (FIG. 4b) of the gas ring liner 402 and set predetermined clearance between the lid liner 242 and the dome lid 224 and between the gas ring liner 402 and the dome lid 224. The separators 404 may be in the form of a continuous ring or be formed by a plurality of segments distributed along the top surface 416 of the gas ring liner 402.

As shown in FIG. 4b, the separators 404 includes at least two separated segments 404a and 404b. According to an embodiment, each segment 404a and 404b covers a predetermined arc angle, such as about 15 to 60 degrees, and in one example is about 45 degrees or 30 degrees. Each segment 404a and 440b has a dome contact side 406 and a liner contact side 408. The dome contact side 406 maintains a continuous contact with the dome lid 224, while the liner contact side 408 includes a few discrete protrusions 410 configured to contact the lid liner 242. Other surface areas of the liner contact side 408 do not in contact with the lid liner 242.

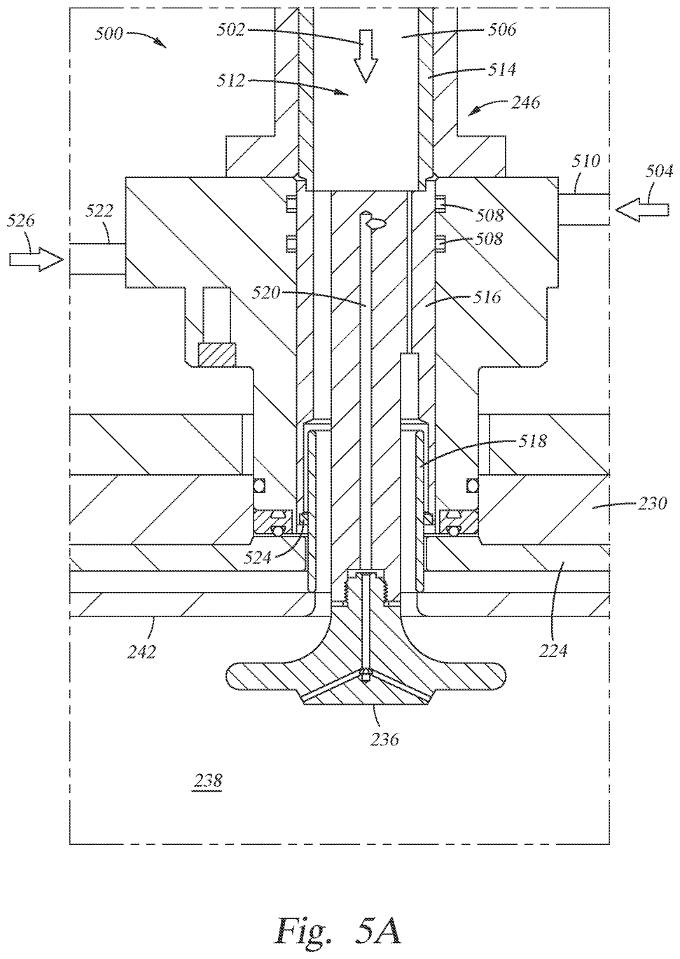

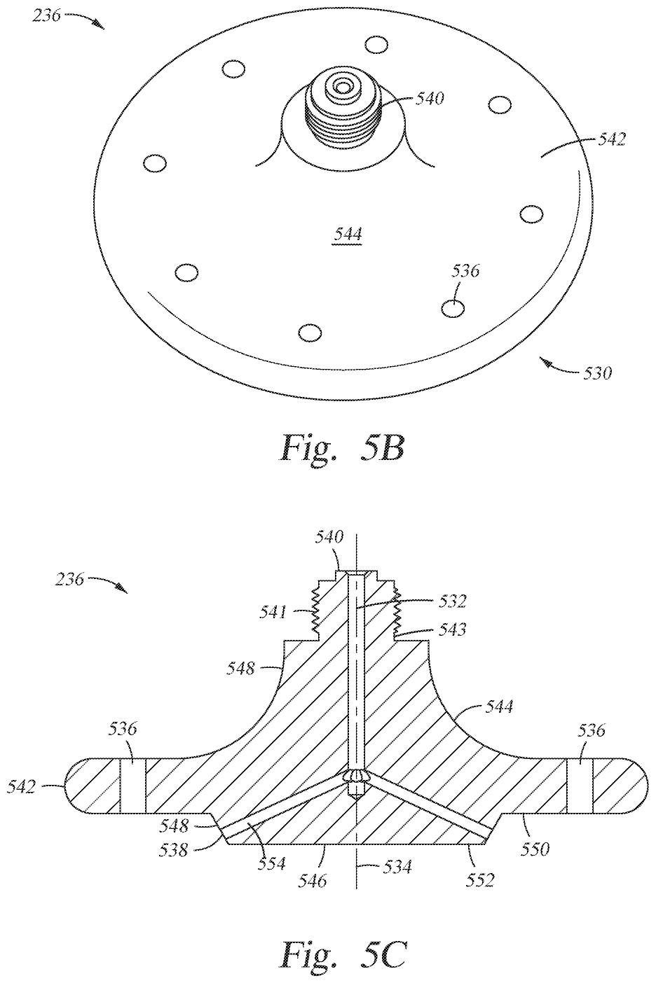

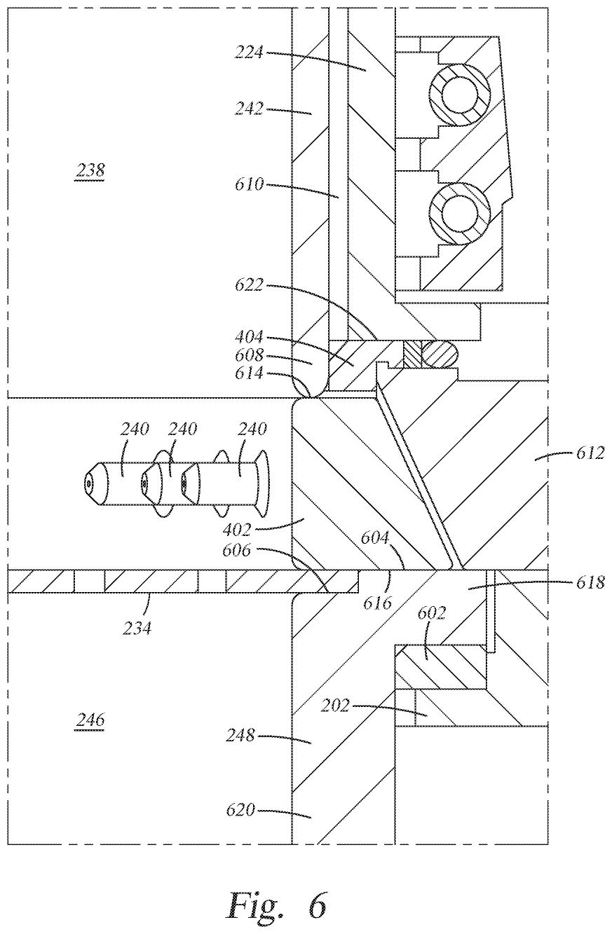

FIG. 4a also shows a gas baffle 236 that extends through the dome lid 224 and the lid liner 242 and into the gas plenum 238 of the processing chamber 200. The configuration of Callout 4-A, including the gas baffle, will be explained in detail in FIG. 5a. The construction configuration of Callout 4-B will be explained in detail in FIG. 6.

FIG. 5a illustrates the configuration of Callout 4-A in FIG. 4a, according to an embodiment. The gas feed section 500 includes a carrier gas conduit 512 for a carrier gas 502 and a deposition/cleaning gas pipe 510 for the deposition/cleaning gas 504. A plasma chamber 506 is disposed at an upper part of the carrier gas conduit 512, where a remote plasma source 252 energizes the carrier gas 502 into a plasma state. The energized carrier gas 502 flows downwardly in the conduit 512 to enter the gas plenum 238. The deposition/cleaning gas 504 flows from the deposition/cleaning gas pipe 510 into a deposition/cleaning gas conduit 520. The gas pipe 510 may further include a plasma chamber coupled with a remote plasma source to energize the deposition/cleaning gas. Two radial seals 508 are disposed above and below the gas pipe 510 along the gas conduit 512. According to an embodiment, the gas pipe 510 is disposed in a direction substantially perpendicular to the gas conduit 520. The carrier gas conduit 512 and the deposition/cleaning gas conduit 520 are substantially coaxial. The deposition/cleaning gas 504 flows downward in the conduit 520 into the gas baffle 236 which spreads the deposition/cleaning gas in the gas plenum 238. Another plasma source 230, such as an inductively coupled plasma source, may be disposed at a top surface of the dome lid 224 to energize the gas mixture in the gas plenum 238.

The gas conduit 512 is protected by a plurality of liners. A plasma chamber liner 514 is disposed within the plasma chamber 506. The carrier gas conduit 512 is protected by two liners: a first liner 518 and a second liner 516. The first liner 518 is disposed at the bottom part of the carrier gas conduit 512 and couples the lid liner 242 with the carrier gas conduit 512. The second liner 516 engages with the first liner 516 via an aligner 524 and couples the first liner 518 with the plasma chamber liner 514. This split liner design eases the alignment and installation process when the gas feed section 500 is assembled. According to an embodiment, the plasma chamber liner 514, the first liner 518, and the second liner 518 may be made of quartz or other suitable materials. The aligner 524 may be made of PTFE or other suitable materials.

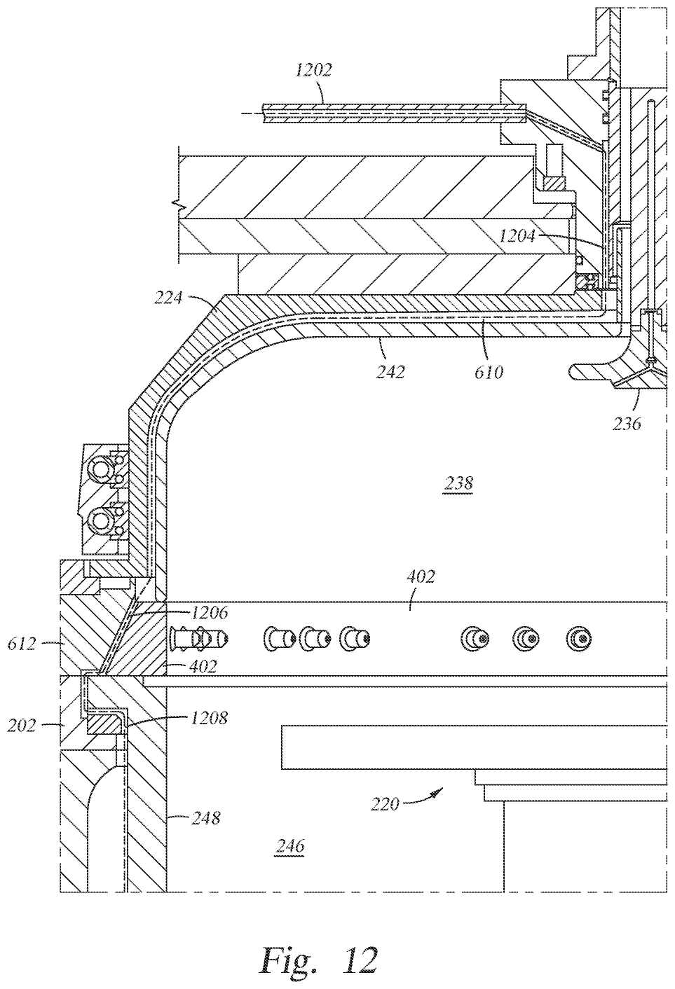

The gas feed section 500 further includes a purge gas pipe 522 for a purge gas. As gaps exist between the internal liners and the dome lid and side walls of the processing chamber 200, process gases could have leaked into those gaps and may generate deposits. The purge gas pipe 522 is configured to flow a purge gas 526 into the gaps to prevent the process gases and/or plasma from entering the gap. The purge gas pipe 522 is coupled with the gaps at a location right below the deposition/cleaning gas pipe 510 and provides the purge gas into those gaps. To allow the purge gas to flow into those gaps, the aligner 524, the separator 404, and the gas ring liner 402 include openings at pre-determined locations for the purge gas to flow through. The flow path of the purge gas will be shown and explained in detail later with reference to FIG. 12.

FIGS. 5b and 5c illustrate schematic perspective and cross-sectional views of the top baffle 236, respectively, according to an embodiment of the present application. The top baffle 236 includes a coupling part 540, an extension part 544, a disk body 542, and a bottom part 546. The top baffle 236 includes a plurality of first channels 532 and 554 for delivering the process gas 504 and a plurality of second channels 536 for delivering the process gas 502.

The coupling part 540 couples the top baffle 236 with the gas liner 516 via a thread 541 or any other suitable coupling mechanism. A groove 543 is formed between the coupling part 540 and the extension part 544 and configured to receive a gas seal. The process gas 504 flows inside the top baffle 236 via the channel 532 that is disposed vertically along an axis 534 of the top baffle 236. The process gas 502 flows along an external surface 548 of the top baffle 236.

The extension part 544 allows the top baffle 236 to have an adequate clearance from the lid liner 242. The extension part 544 also allows the top baffle 236 to reach a predetermined depth within the gas plenum 238. The extension part 544 is configured to extend radially outward from the coupling part 540 to direct the process gas 502 away from the axis 534 of the top baffle 236. According to an embodiment, an external surface 548 of the extension part 544 represents a quarter circle that extends from the coupling part 540 to the disk body 542.

The disk body 542 has a substantially circular shape 530. The disk body 542 includes a plurality of gas channels 536 that allow the process gas 502 to flow through. The plurality of gas channels 536 are arranged in parallel to the axis 534. The extension part 544 and the channels 536 together distribute the process gas 502 into the gas plenum 238.

The bottom part 546 has a circular shape with a smaller diameter than the diameter of the disk body 542. The bottom part 546 extends from a bottom surface 550 of the disk body 542. A beveled surface 548 is formed between the bottom surface 550 of the disk body 542 and a bottom surface 552 of the bottom part 546. The beveled surface 548 includes a plurality of dispensing outlets 538 of a plurality of channels 554, which direct the process gas 504 radially outward from the channel 532. In this way, the process gas 504 can be distributed more evenly into the gas plenum 238. According to an embodiment, the channel 554 and the vertical channel 532 form an angle of about 60 degrees.

FIG. 6 illustrates a construction configuration of Callout 4-B in FIG. 4a according to an embodiment. The lid liner 242, the gas ring liner 402, and the wall liner 248 may rest on top of each other as they can be made of similar materials, such as quartz. For example, a lower end 608 of the lid liner 242 rests on a top surface 614 of the gas ring liner 402, whose bottom surface 616 rests on an upper end 604 of the wall liner 248. The wall liner 248 is configured to couple with both the gas ring liner 402 and, optionally, the showerhead 234. According to an embodiment, the upper end 604 of the wall liner 248 is substantially “L” shaped. The cantilever extension 618 of the upper end 604 couples with a separator 602, which separates the wall liner 248 from the side wall 202. The separator 602 may be made of PTFE or similar materials. According to an embodiment, the wall liner 248 has an open lower end 620 to allow process gas to flow through. According to an embodiment, the upper end 604 include an optional cutout 606 configured to couple with the showerhead 234. The optional cutout 606 has a thickness similar with the showerhead 234 such that after the showerhead 234 is disposed within the cutout 606, the top surface of the showerhead 234 is flushed with the top surface of the upper end 604. The gas ring liner 402 rests on both the showerhead 234 and the wall liner 248. In this way, the showerhead 234 is snuggly sandwiched by the gas ring liner 402 and the wall liner 248.

As shown in FIG. 6, the separator 404 separates both the lid liner 242 and the gas ring liner 402 from other outside components, such as the lid 224 and a gas ring 612. According to an embodiment, the separator 404 maintains a clearance gap 610 between the dome lid 224 and the lid liner 242.

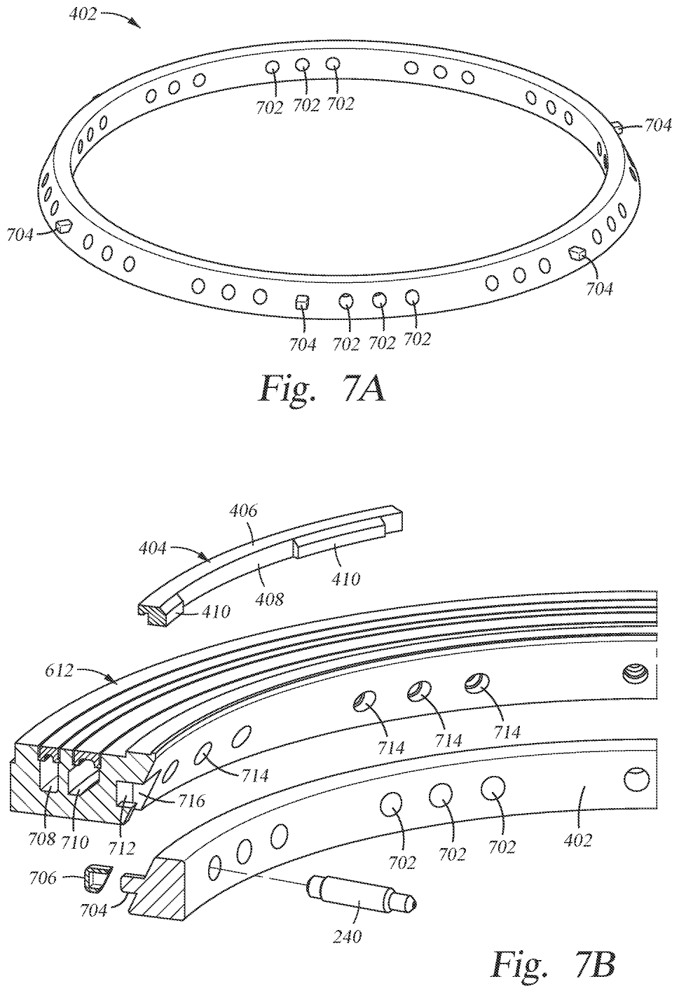

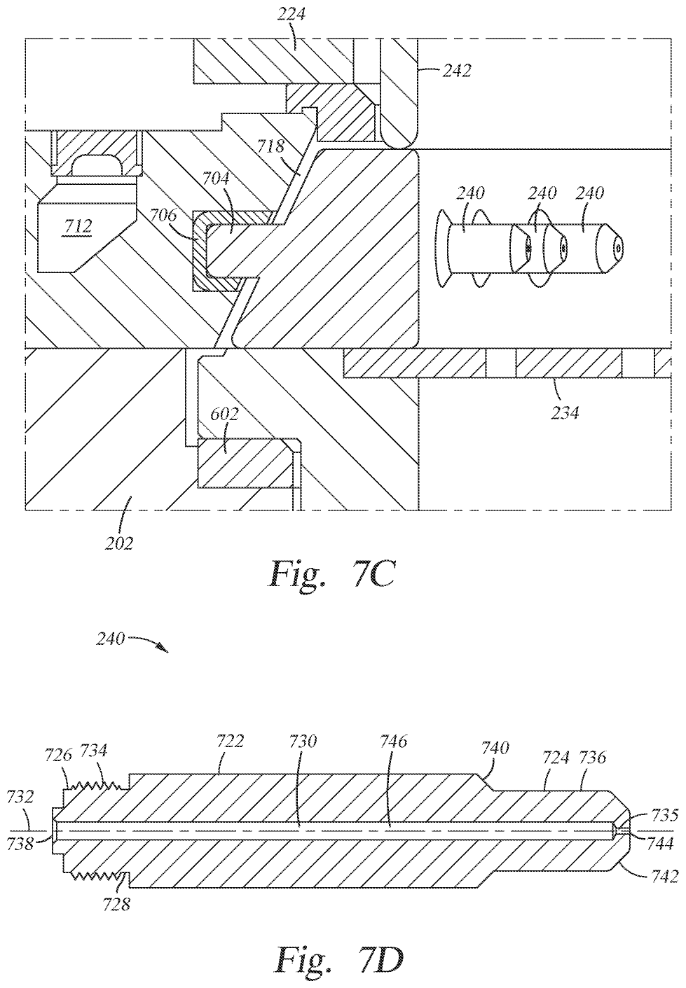

FIGS. 7a-c illustrate configurations between a gas ring liner and a gas ring according to an embodiment. A gas ring 612 is disposed between the dome lid 224 and the side walls 202 to provide process gases into the side nozzles 240. The gas ring 612 includes a plurality of concentric gas channels 708, 710, and 712 configured to flow process gases to respective side nozzles 240. The gas ring 612 further includes a plurality of apertures 714 that couple with the side nozzles 240. The gas ring 612 may further couple with the separator 404 having a plurality of protrusions 410 as shown in FIG. 4b. The gas ring liner 402 is disposed inward of the gas ring 612 to protect and insulate the gas ring 612 from the process gases and the heat. The gas ring liner 402 includes a plurality of apertures 702, a plurality of tabs 704, and a plurality of separators 706. The plurality of apertures 702 align with the plurality of apertures 714 of the gas ring 612 such that the side nozzles 240 extend through both apertures. The plurality of tabs 704 engage with corresponding depressions 716 disposed in the gas ring 612 such that the gas ring liner 402 is properly aligned with the gas ring 612 and radial movement of the gas ring liner 402 may be mitigated. As the gas ring liner 402 and the gas ring 612 may be made of different materials, each tab 704 may have a separator 706 for maintaining a clearance gap 718 with the gas ring 612 to accommodate thermal expansion. The separator 706 may be made of PTFE or other suitable materials.

FIG. 7d illustrates a schematic cross-sectional view of a side nozzle 240, according to an embodiment of the present application. The side nozzle 240 has a cylindrical shape with a central axis 732. The side nozzle 240 includes a coupling part 726, an extension body 722, and a nozzle part 724, each having a cylindrical shape but with different diameters. The coupling part 726 is configured to couple with the gas ring 612 and has an orifice 738 to allow a process gas to flow into a channel 730 disposed within the side nozzle 240. The coupling part 726 may couple with the gas ring 612 via any suitable coupling mechanisms, such as a plurality of threads 734. A protrusion 725 is disposed around the orifice 738 and extends from a bottom surface of the coupling part 726. The protrusion 725 is configured to couple with the aperture 714 via a separator made of PTFE. A groove 728 is formed between the coupling part 726 and the extension body 722 and is configured to accommodate a gas seal. The extension part 722 has a larger diameter than the coupling part 726. The extension part 722 has a length that is about the same as the thickness of the gas ring liner 402 to allow the nozzle part 724 to be positioned inside the gas plenum 238.

The nozzle part 724 has a smaller diameter than the extension part 722 to reduce obstruction of gas flow inside the gas plenum 238. The nozzle part 724 includes a first beveled part 740, a support body 736, a second beveled part 742, and a dispenser outlet 744. The first beveled part 740 connects the extension body 722 with the support body 736. The second beveled part 742 connects the support body 736 with the dispenser outlet 744.

The channel 730 extends along the axis 732 from the orifice 738 to the dispenser outlet 744. According to an embodiment, the channel 730 includes a first segment 746 and a second segment 735. The first segment 746 traverses the coupling part 726, the extension body 722, and a portion of the nozzle part 724. The second segment 735 is entirely disposed within the nozzle part 724 and couples directly with the dispenser outlet 744. According to an embodiment, a diameter of the second segment 735 is smaller than a diameter of the first segment 746.

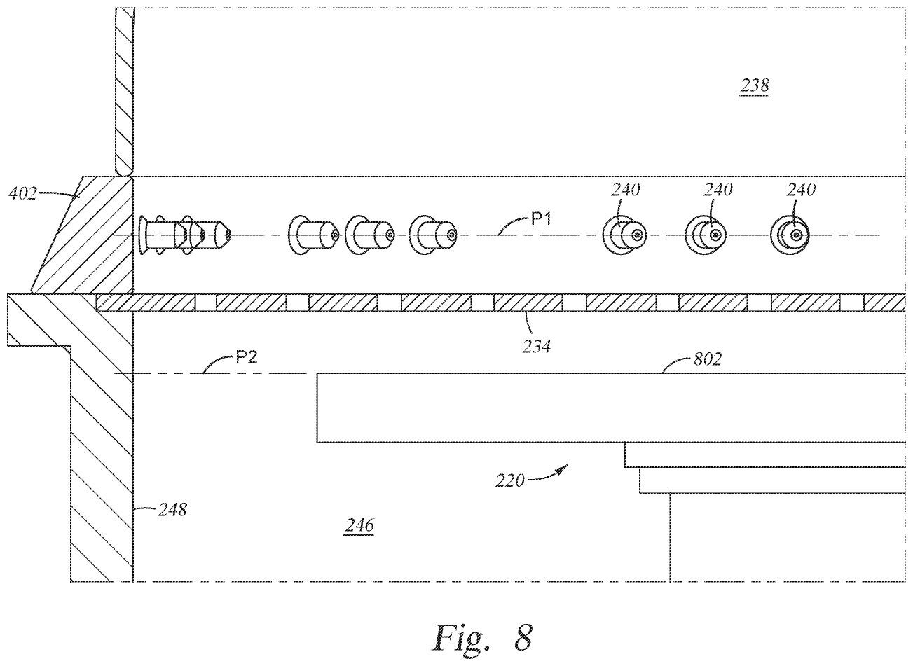

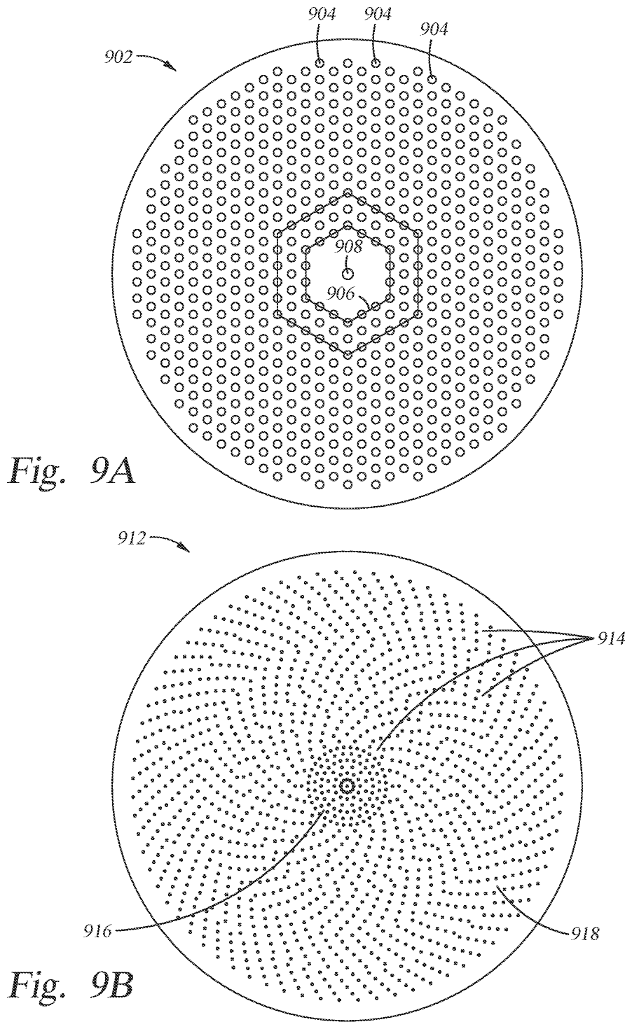

FIG. 8 illustrates a schematic configuration of the processing chamber including the optional showerhead 234 and the susceptor 220, according to an embodiment. The showerhead 234 rests on the wall liner 248 and is disposed between the plurality of side nozzles 240 and a top surface 802 of the susceptor 220. For example, the distance between the showerhead 234 and a plane P1 passing the centers of the plurality of the side nozzles 240 may be approximately equal to the distance between the showerhead 234 and a plane P2 passing the top surface 802 of the susceptor 220.

FIG. 9a illustrates a schematic top view of a showerhead according to an embodiment. The showerhead 902 of FIG. 9a may include a plurality of through apertures 904 that allow process gases to flow through. According to an embodiment, the plurality of through apertures 904 are arranged in a plurality of equal sided hexagons 906 that share a common center 908 of the showerhead 902. According to an embodiment, the apertures 904 are disposed equidistantly along the perimeter of each hexagon. According to an embodiment, the sizes of the apertures 904 are between 0.1 to 0.4 inch.

FIG. 9b illustrates a schematic top view of a showerhead according to an embodiment. The showerhead 912 includes a plurality of apertures 914, whose sizes are relatively small, such as between 0.01 to 0.08 inch, compared to the apertures 904 of the showerhead 902. The arrangement of the apertures 914 may include a plurality of patterns. For example, around a central zone 916 of the showerhead 912, a plurality of apertures 914 are disposed in concentric circles, while at the peripheral areas 918 of the showerhead 912, a plurality of apertures are disposed in a zigzag pattern.

According to an embodiment, the showerhead 234 is made of a dielectric material, such as quartz, sapphire, alumina, boron nitride (Pyrolytic), or other suitable material. A dielectric showerhead 234 allows the gas to be energized at a high power level to flow through and reach the surface of a substrate 210. According to another embodiment, the showerhead 234 is made of a conductive material, such as aluminum coated with alumina or silicon or a passivated layer, or other suitable material. A conductive showerhead 234 will allow more radicals to reach the surface of a substrate.

FIG. 10a illustrates a schematic cross-sectional view of the susceptor 220 according to an embodiment. The susceptor 220 includes a top cover 1002, a heater body 1012, a bottom cover 1004, a column support cover 1006, and a support column 1022. In an example, the heater body 1012 and the support column 1022 are made of aluminum nitride or aluminum oxide. According to an embodiment, the top cover 1002 and the bottom cover 1004 are made of materials resistant to process gases, such as chlorine gas or chlorine containing gas mixtures. In one example, the top cover 1002 and the bottom cover 1004 are made of boron nitride (paralytic-) (PBN). The column support cover 1006 may be made of similar materials as the top cover 1002 and bottom cover 1004. The top cover 1002, the bottom cover 1004, and the column support cover 1006 are configured to encapsulate substantially all surfaces of the heater body 1012 and the support column 1022 to protect them from corrosion by process gases. According to an embodiment, the top cover 1002 contacts with a substrate 210 and has a high thermal conductivity. The bottom cover 1004 is configured to reduce thermal loss and has a low thermal conductivity. According to an embodiment, the top cover 1002 is configured to have a higher thermal conductivity than the bottom cover 1004.

According to an embodiment, the susceptor 220 further includes a plurality of heat transfer channels disposed within the susceptor 220 configured to assist heat transfer to the surface arear of the heater body 1012. Details of the heat transfer channels will be described with reference to FIGS. 10b and 10c.

The heater body 1012 is covered by the top cover 1004, the bottom cover 1004, and the column support cover 1006. According to an embodiment, the heater body 012 is substantially T-shaped with a horizontal cap 1030 coupled with a column support 1022. The top cover 1002 and the bottom cover 1004 overlay each other where they meet to avoid exposing the heater body 1012 to the process gases. The top cover 1002, the bottom cover 1004, and the heater body 1012 include a plurality of lift pin holes 1010, 1026, and 1028, respectively. The lift pin holes 1010, 1026, and 1028 are aligned with each other to allow lift pins to pass through. According to an embodiment, the top cover 1002 further includes a plurality of alignment pins 1032 disposed at a central location of the top cover 1002. The heater body 1012 includes a plurality of alignment depressions 1034 to receive the alignment pins 1032. The alignment pins 1032 and depression 1034 are configured to align lift pin holes 1010 in the top cover and the lift pin holes 1028 in the heater body 1012. According to an embodiment, alignment pins are also disposed in the bottom cover 1004.

The column support 1022 is protected by a column support cover 1006 which is also made of a corrosion-resistant material, such as a chlorine-resistant material. The column support 1022 and the column support cover 1006 are coupled with each other coaxially. The column support cover 1006 overlaps with the bottom cover 1004 to prevent process gas from contacting the heater body 1012. A plurality of electrical connections 1014 are disposed within the column support 1022.

FIG. 10b illustrates a schematic top view of the heater body 1012 according to an embodiment. The plurality of channels 1044 are disposed on a top surface 1042 of the heater body 1012. In one embodiment, the plurality of channels 1044 are configured to transfer inert gases, such as argon gas or any other suitable gases, to the peripheral areas of the heater body 1012 to maintain a constant rate of heat transfer across the entire heater surface. The plurality of channels include inner channels 1046, branch channels 1048, and peripheral channels 1050. The inner channels 1046 couple with the alignment depression 1034 and are configured to distribute the gases from the alignment depressions 1034 to the branch channels 1048. The branch channels 1048 are configured to provide the gases from the inner channels 1046 to the peripheral channels 1050 that cover a substantially amount of peripheral areas. In one example, the inner channels 1046 form a circle around an axis 1052 of the heater body 1012. The branch channels 1048 are straight channels configured to lower the resistance when gases are delivered from inner channels to the peripheral channels. The peripheral channels 1050 also form a circle that is coaxial with the inner channels 1046.

FIG. 10c illustrates a schematic cross-sectional view of the heater body 1012. The column support 1022 includes a plurality of gas channels 1058 disposed in parallel with the axis 1052. The plurality of gas channels 1058 are coupled with the plurality of channels 1044 (also shown in FIG. 10b) via the alignment depressions 1034. The column support 1022 further includes a main channel 1054 coupled with both a gas inlet 1018 (shown in FIG. 10a) and a branch channel 1056. Purge gases flow from the gas inlet 1018 to the main channel 1054 and then to the branch channel 1056, which distributes the gases to the plurality of gas channels 1058. In one embodiment, the number of gas channels 1058 is the same as the number of the alignment depressions 1034.

During operation, the column support cover 1006 and the heater body 1012 may be lifted together by a lifter 244 (shown in FIG. 3). Thus, a sleeve 1016 attached to the bottom 204 (shown in FIG. 3) is included to provide a conduit to guide the movement of the column support cover 1006 and the heater body 1012. According to an embodiment, the column support cover 1006 and the sleeve 1016 engage with each other to form a gas-tight seal. In one example, the column support cover 1006 includes a bottom flange 1024 that engages with an end of the sleeve 1016 to form a gas tight seal when the column support cover 1006 is lifted up. The bottom flange 1024 may include a groove. According to another embodiment, the column support cover 1006 also includes a bottom purge flange 1020 having a plurality of gas inlets 1018. The plurality of gas inlets 1018 are coupled with purge gas pipes 304 (shown in FIG. 3) configured to flow purge gas to the space or volume inside the column support cover 1006. The purge gas creates a positive pressure inside the column support cover 1006, which can prevent process gas from entering the inside of the column support cover 1006, depositing materials inside the column support 1022, and corroding the heater body 1012.

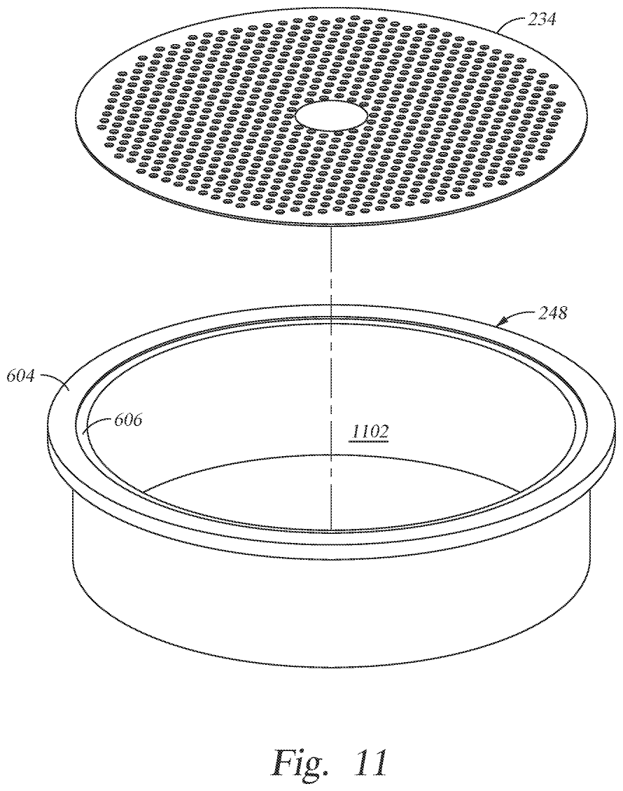

FIG. 11 illustrates a schematic perspective view of a wall liner 248 according to an embodiment. The wall liner 248 has a cylindrical shape with an open end 1102 that allows the process gases to flow through. A vacuum pump 214 (FIG. 2) is disposed below the wall liner 248 to remove the process gases. The wall liner 248 has an upper end 604 that has an “L” shape. The upper end 604 has a cantilever extension configured to couple with the side wall 202 (FIG. 2) of the processing chamber 200 via a separator. The upper end 604 further includes a cutout 606 configured to couple with the showerhead 234.

FIG. 12 illustrates a schematic flow path of a purge gas according to an embodiment of the present application. When the liners are disposed between other outside parts of the processing chamber 200 and an internal region, gaps are created between the liners and other outside parts. For example, a gap 1204 is created between the conduit liners 514, 516, 518 and the conduits 512. Another gap 610 is created between the lid liner 242 and the dome lid 224. Yet another gap 1206 is created between the gas ring 612 and the gas ring liner 402. And yet another gap 1208 is created between the wall liner 248 and the side walls 202. As these gaps are not completely sealed from the process gases, these gaps are filed with a purge gas to prevent the process gases from entering during a substrate processing. The purge gas prevents any deposition of materials in these gaps and possible contamination during the processing of the next substrate.

According to an embodiment, gaps between the liners and outside parts are configured to be fluidly coupled with each other such that a purge gas can flow from one gap to another. As shown in FIG. 12, a purge gas pipe 1202 is coupled with the gap 1204 at a location right below the process gas pipe. The purge gas pipe 1202 is configured to flow a purge gas, such as an inert gas, with pressure into the gap 1204. With the pressure from the purge gas pipe 1202 and the vacuum from the vacuum pump 214 at the bottom, the purge gas flows from the gap 1204 to the gap 610, the gap 1206, and the gap 1208, and then exits the processing chamber 200 via the vacuum pump 214. The dash line shown in FIG. 12 indicates the flow path of the purge gas in the processing chamber 200. According to an embodiment, to allow the purge gas flow through the gaps, the separators are configured to have intermittent openings that couple adjacent gaps.

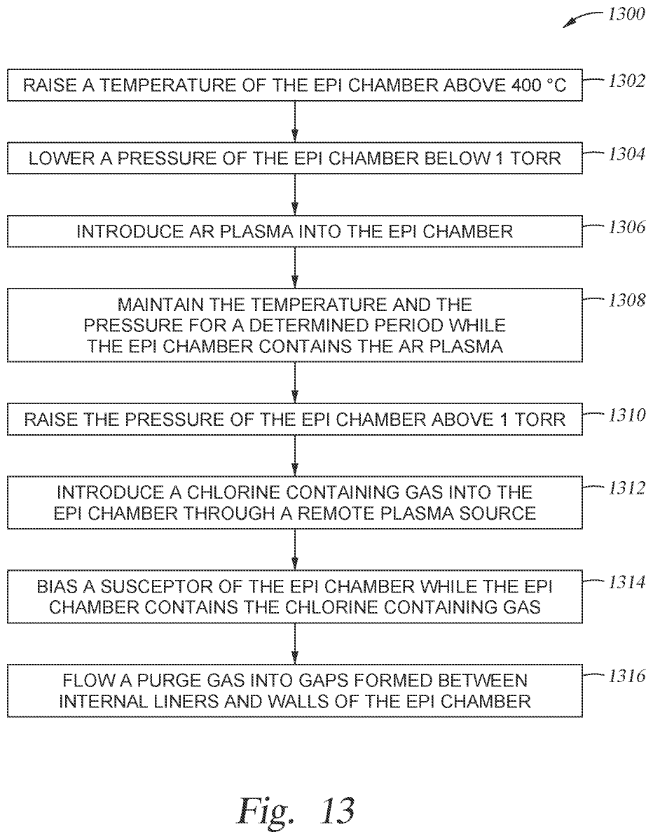

FIG. 13 illustrates a block diagram of a cleaning method 1300 of the EPI chamber according to an embodiment. The in-situ chamber cleaning process cleans chamber walls and the susceptor. The in-situ chamber cleaning process may use a chlorine containing gas. A plasma may also be generated during the cleaning process. The temperature of the susceptor may be increased before the cleaning process and decreased after the cleaning process. The cleaning method 1300 starts with operation 1302 which raises a temperature of the EPI chamber above about 400° C. At operation 1304, the pressure of the EPI chamber is lowered below about 100 m Torr, such as between 5 and 20 mTorr. At operation 1306, an argon plasma is introduced into the EPI chamber. The plasma source disposed around the chamber walls may also be activated to further energize the argon plasma. At operation 1308, the temperature and the pressure are maintained for a determined period while the EPI chamber contains the argon plasma. The argon plasma is continuously introduced. At operation 1310, the pressure of the EPI chamber is maintained or adjusted to a property range suitable to strike a chlorine plasma. At operation 1312, a chlorine containing gas is introduced into the EPI chamber while the argon plasma is maintained. The power to generate the argon plasma will be increased due to the introduction of the chlorine containing gas. The chlorine containing gas is introduced for a predetermined period to assist the cleaning of surfaces previously exposed to the argon plasma. At operation 1314, a purge gas may be flowed into gaps formed between internal liners and walls of the EPI chamber. The operation 1314 may be implemented together with any operations of the cleaning method 1300. According to an embodiment, the operation 1314 is implemented before introducing the chlorine containing gas into the chamber to protect certain surfaces that may not be compatible with the chlorine containing gas.

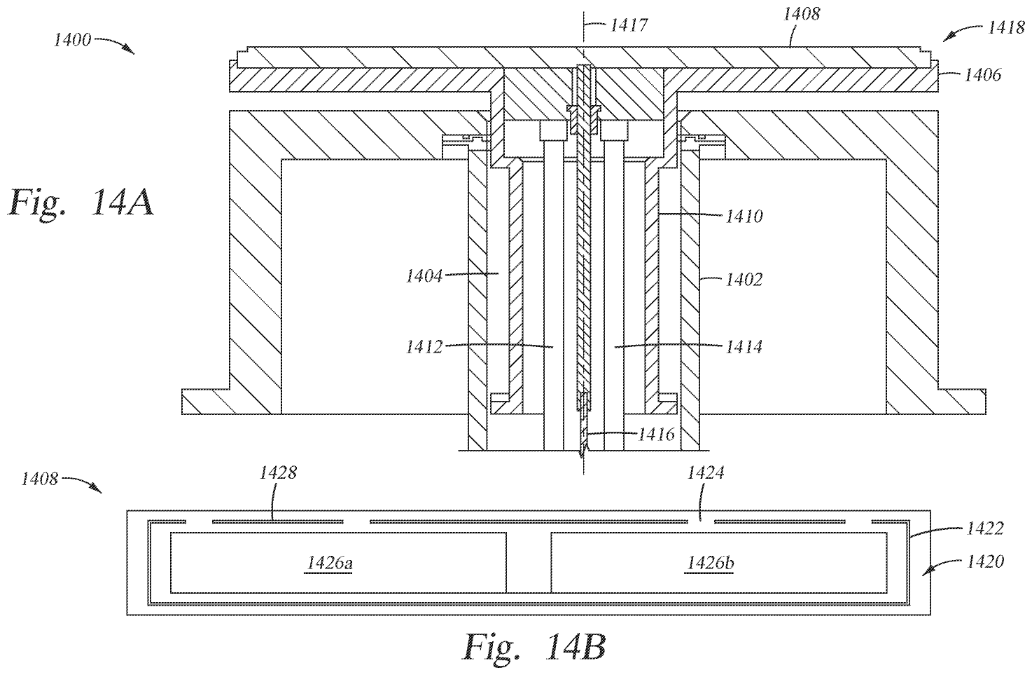

FIG. 14a illustrates a schematic cross-sectional view of a susceptor 1400, according to an embodiment. The susceptor 1400 includes a heater puck 1408, a support body 1406, and a shaft 1410. The heater puck 1408 is disposed on the support body 1406 and includes a plurality of resistive heating elements (such as 1428 shown in FIG. 14b) configured to heat a substrate disposed on the heater puck 1408. The support body 1408 includes a rim 1418 disposed around the perimeter. The rim 1418 forms a pocket that contains the heater puck 1408. The support body 1406 is coupled with the shaft 1410. The shaft 1410 can be raised up and lowered down by an actuator (such as the lifter 244 in FIG. 2). A sleeve 1402 surrounds the shaft 1410 with a certain clearance space 1404 to allow the shaft 1410 move up and down. The clearance space 1404 also functions as a purged volume 1404, which is filled with a pressured purge gas, such as an argon gas, during a substrate processing. The pressured purged gas prevents process gases from entering the internal space of the susceptor 1400.

The susceptor 1400 further includes a plurality of electric conduits 1412 and 1414 configured to allow electric wires to pass through. The susceptor 1400 may also include channel 1416 disposed along a central axis 1417 of the susceptor 1400. The channel 1414 allows a temperature probe to measure the temperature of the heater puck 1408.

FIG. 14b illustrates a schematic cross-sectional view of the heater puck 1408, according to an embodiment. The heater puck 1408 includes a plurality of graphite cores 1426a and 1426b that are enclosed by a first protective layer 1424. The first protective layer 1424 may be made of boron nitride (paralytic-) (PBN). The plurality of resistive heating elements 1422 are disposed on the first protective layer 1424 and then covered by a second protective layer 1420. The second protective layer 1420 may be made of a material similar with that of the first protective layer 1424. Each graphite core 1426a or 1426b is enclosed by the first protective layer 1424. The first layer 1420 and the second 1424 may be formed by two coatings of PBN or by sintering two plates made of PBN.

It is contemplated that one or more aspects disclosed herein may be combined. Moreover, it is contemplated that one or more aspects disclosed herein may include some or all of the aforementioned benefits. While the foregoing is directed to embodiments of the present disclosure, other and further embodiments of the disclosure may be devised without departing from the basic scope thereof, and the scope thereof is determined by the claims that follow.

What is claimed is:

1. A processing chamber for an epitaxy deposition comprising:
a dome lid coupled with a lid liner via a lid liner separator;
a plasma source disposed on top of the dome lid and operable to energize a process gas;
a gas ring disposed under the dome lid and coupled with a gas ring liner via a gas ring liner separator;
a susceptor disposed below the gas ring and operable to heat a substrate; and
a side wall disposed under the gas ring and coupled with a wall liner via a wall liner separator.

2. The processing chamber of claim 1, wherein the lid liner separator comprises a plurality of segments disposed along a lower end of the dome lid and configured to allow a purge gas to flow through.

3. The processing chamber of claim 1, wherein the gas ring liner further comprising a plurality of tabs configured to couple with corresponding depressions disposed on the gas ring.

4. The processing chamber of claim 3, wherein the gas ring liner separator is disposed on the plurality of tabs.

5. The processing chamber of claim 1, further comprising a side nozzle coupled with the gas ring and the gas ring liner, wherein the side nozzle comprises a cylindrical shape with a gas channel disposed along a central axis of the side nozzle.

6. The processing chamber of claim 5, wherein the side nozzle comprise:
a dispenser outlet disposed at one end of the side nozzle and configured to provide the process gas into the processing chamber; and
an orifice disposed at another end of the side nozzle and configured to receive the process gas from the gas ring, the orifice being surrounded by an protrusion extending from a surface of the side nozzle.

7. The processing chamber of claim 1, further comprising a gas conduit disposed outside the dome lid and configured to provide the process gas to the processing chamber, the gas conduit comprising a gas conduit liner and a plasma chamber.

8. The processing chamber of claim 7, further comprising a gas baffle disposed under the dome lid and coupled with the gas conduit.

9. The processing chamber of claim 8, wherein the gas baffle comprises a coupling part coupled with the gas conduit liner, an extension part extending from the coupling part toward the susceptor, a disk body coupled with the extension part and comprising a plurality of first gas outlets that are parallel with an axis of the gas baffle, and a bottom part extending from the disk body and comprising a beveled surface that comprises a plurality of second gas outlets.

10. The processing chamber of claim 9, wherein the gas conduit is coupled with a first purge gas pipe operable to flow a first purge gas into a gap between the gas conduit and the gas conduit liner.

11. The processing chamber of claim 1, wherein the susceptor further comprises a heater puck supported by a base body, the heater puck comprising a plurality of graphite cores.

12. The processing chamber of claim 11, wherein the heater puck comprises a first protection layer enclosing the plurality of graphite cores.

13. The processing chamber of claim 12, wherein the heater puck further comprises a plurality of resistive heating elements disposed along an external surface of the first protection layer and a second protection layer enclosing the plurality of the resistive heating elements.

14. The processing chamber of claim 13, wherein the susceptor further comprises a sleeve coaxially disposed along a leg of the susceptor and configured to form a purge conduit between the sleeve and the leg.

15. The processing chamber of claim 1, further comprising a first plasma source disposed around walls above the gas ring of the dome lid and a second plasma source disposed around walls below the gas ring of the dome lid.

16. The processing chamber of claim 15, wherein the plasma source disposed on top of the dome lid, the first plasma source, and the second plasma source are capable of independently energizing the process gas inside the processing chamber.

17. The processing chamber of claim 1, wherein a temperature of the substrate during the epitaxy deposition is below 500° C.

18. A method for cleaning an EPI chamber, comprising:
raising a temperature of the EPI chamber above about 400° C.;
lowering a pressure of the EPI chamber to a range of between about 5 and about 20 mTorr;
introducing argon gas into the EPI chamber;
maintaining the temperature and the pressure for a determined period while the EPI chamber contains the argon gas;
adjusting the pressure of the EPI chamber for striking a chlorine plasma;
introducing a chlorine containing gas into the EPI chamber through a remote plasma source; and
flowing a purge gas into gaps formed between internal liners and walls of the EPI chamber.

19. A side nozzle for providing a process gas to an EPI chamber, the side nozzle comprising:
a cylindrical body comprising a coupling part comprising an orifice, an extension body, and a nozzle part comprising a dispenser outlet, the extension body being disposed between the coupling part and the nozzle part and comprising a larger diameter than the coupling part and the nozzle part; and
a gas channel disposed along a central axis of the cylindrical body.

20. The side nozzle of claim 19, further wherein the orifice disposed is configured to receive the process gas from a gas ring and is surrounded by a protrusion extending from a surface of the side nozzle.

21. The side nozzle of claim 20, further comprising a groove disposed between the coupling part and the extension body and gas seal disposed in the groove.

22. A susceptor for heating a substrate in a processing chamber, the susceptor comprising:
a heater puck supported by a base body; and
a shaft coupled with the base body and enclosed by a sleeve,
wherein the heater puck comprises a plurality of graphite cores enclosed by a first protection layer, a plurality of resistive heating elements disposed on a surface of the first protection layer, and a second protection layer enclosing the plurality of resistive heating elements.

23. The susceptor of claim 22, further comprising a temperature measurement channel disposed along a central axis of the susceptor.
